(19) United States
(12) Patent Application Publication
(10) Pub. No.: US 2026/0182447 A1
(43) Pub. Date: Jun. 25, 2026

(54) PACKAGE STRUCTURE AND METHOD OF FORMING THE SAME

(71) Applicant: Taiwan Semiconductor Manufacturing Company, Ltd., Hsinchu (TW)

(72) Inventors: Chao-Wei Li, Hsinchu City (TW); Pei-Hsuan Lee, Tainan City (TW); Cheng-Chi Hsieh, Hsinchu City (TW); Yu-Hsiang Hu, Hsinchu City (TW); Chien-Hsun Lee, Hsin-chu County (TW); Kathy Wei Yan, Hsinchu (TW)

(73) Assignee: Taiwan Semiconductor Manufacturing Company, Ltd., Hsinchu (TW)

(21) Appl. No.: 18/988,681

(22) Filed: Dec. 19, 2024

(51) Int. Cl. H01L 23/053; H01L 21/56; H01L 23/00; H01L 23/31; H01L 23/42; H01L 23/498; H01L 23/538; H01L 25/065; H01L 25/16; H10B 80/00; H10D 89/10

(52) U.S. Cl. CPC H10W 76/15; H10W 40/70; H10W 70/611; H10W 70/65; H10W 74/016; H10W 74/141; H10W 90/401; H10B 80/00; H10D 89/10; H10W 74/15; H10W 90/00; H10W 90/724; H10W 90/734

(57) ABSTRACT

A package structure and a method of forming the same are provided. The package structure includes a circuit substrate, a package unit disposed on and electrically connected to the circuit substrate, a molding layer disposed on the circuit substrate, a thermal interface material (TIM) disposed on the package unit; a lid disposed on the TIM and adhered to the package unit through the TIM. The molding layer surrounds the package unit and covers sidewalls of the package unit.

### BACKGROUND

Integration of multiple semiconductor devices and electronic components requires advanced packaging and assembling techniques.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic cross-sectional view of a semiconductor package in accordance with some embodiments of the present disclosure.

FIG. 2A through FIG. 2D′ are schematic cross-sectional views and top views schematically illustrate various stages of a process for fabricating a package structure in accordance with some embodiments of the present disclosure.

FIG. 3A through FIG. 3D are schematic cross-sectional views and top views schematically illustrate various stages of a process for fabricating a package structure in accordance with some embodiments of the present disclosure.

FIG. 4A to FIG. 4B are schematic cross-sectional views schematically illustrate various stages of a process for fabricating a package structure in accordance with some embodiments of the present disclosure.

FIG. 5A to FIG. 5B are schematic cross-sectional views schematically illustrate various stages of a process for fabricating a package structure in accordance with some embodiments of the present disclosure.

FIG. 6 to FIG. 8 illustrate schematic cross-sectional view of a package structure in accordance with some embodiments of the present disclosure.

FIG. 9A through FIG. 9C are schematic cross-sectional views schematically illustrate various stages of a process for fabricating a package structure in accordance with some embodiments of the present disclosure.

FIG. 10A to FIG. 10B are schematic cross-sectional views schematically illustrate various stages of a process for fabricating a package structure in accordance with some embodiments of the present disclosure.

FIG. 11A to FIG. 11B are schematic cross-sectional views schematically illustrate various stages of a process for fabricating a package structure in accordance with some embodiments of the present disclosure.

FIG. 12A to FIG. 12B are schematic cross-sectional views schematically illustrate various stages of a process for fabricating a package structure in accordance with some embodiments of the present disclosure.

FIG. 13 to FIG. 14 illustrate schematic cross-sectional view of a package structure in accordance with some embodiments of the present disclosure.

### DESCRIPTION OF THE EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

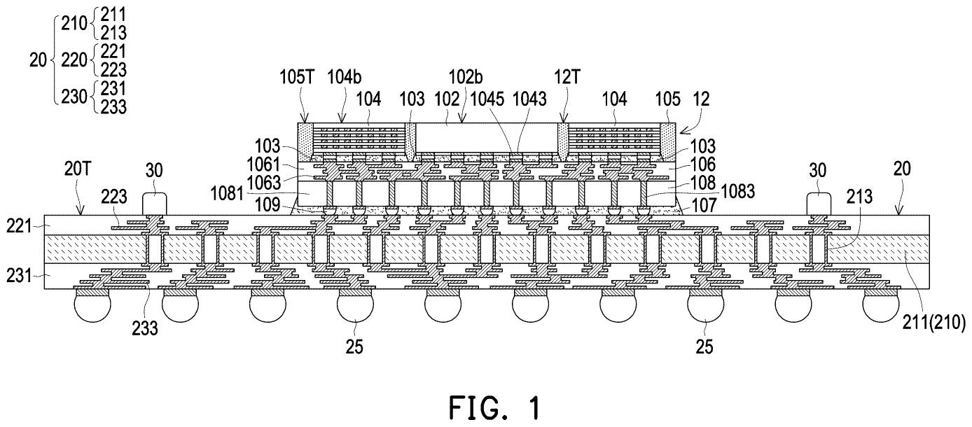

FIG. 1 illustrates a schematic cross-sectional view of a package unit in accordance with some embodiments of the present disclosure.

Referring to FIG. 1, one or more package units 12 and a circuit substrate 20 are provided. In some embodiments, the circuit substrate 20 includes a core layer 210 and build-up layers 220, 230 disposed on opposite sides of the core layer 210. The core layer 210 may include a dielectric layer 211 having plated through holes 213 which extend cross the dielectric layer 211 from side to side. In some embodiments, the plated through holes 213 are electrically conductive and may be partially filled or fully filled. In some embodiments, each build-up layer 220 or 230 respectively includes a dielectric layer 221 or 231 and conductive patterns 223 or 233 embedded in the corresponding dielectric layer 221 or 231 and providing electrical connection between opposite sides of the corresponding dielectric layer 221 or 231. In some embodiments, the circuit substrate 20 with the build-up layers 220, 230 provides electrical connection for devices or components bonded to both sides (double side connection). In some embodiments, the circuit substrate 20 provided may have multiple core layers or stacks for further connection. Although it is not shown in the figure, it is understood that the circuit substrate 20 may be carried or supported by a carrier or a carrying frame.

Referring to FIG. 1, in some embodiments, one or more package units 12 (only one is shown) are mounted onto and connected to a top surface 20T of the circuit substrate 20, and a plurality of passive components 30 are mounted onto and bonded to the top surface 20T of the circuit substrate 20 and beside the package unit(s) 12. In some embodiments, the passive components 30 include or are capacitors, inductors, resistors, diodes, transformers or combinations thereof. In some embodiments, the package unit 12 and the circuit substrate 20 are included in a semiconductor package. In some embodiments, the semiconductor package includes or is a chip-on-wafer-on-substrate (CoWoS) package, and the package unit 12 is bonded to and electrically connected with the circuit substrate 20 through electrical connectors 109. In some other embodiments, the semiconductor package may be an integrated fan-out (InFO) package. In some embodiments, a thickness of the semiconductor package is in a range of about 800 μm to 1100 μm.

In some embodiments, the package unit 12 includes three semiconductor dies or more, and one semiconductor die 102 and two semiconductor dies 104 are shown in the cross-sectional view of the figure as an example. In some embodiments, the semiconductor dies 102, 104 may independently be or include a logic die, such as a central processing unit (CPU) die, a graphic processing unit (GPU) die, a micro control unit (MCU) die, an input-output (I/O) die, a baseband (BB) die, a system-on-chip (SoC) die, a large-scale integrated circuit (LSI) die, or an application processor (AP) die In some embodiments, the semiconductor die 102 includes or is a SoC die and the semiconductor dies 104 include or are HBM dies. The disclosure is not limited by the types of dies included in the package unit 12.

Referring to FIG. 1, an encapsulant 105 is formed over the redistribution layer 106 and the interposer 108 wrapping the semiconductor dies 102, 104. In some embodiments, the semiconductor dies 102, 104 are disposed with the active surfaces facing the interposer 108 and are bonded to the redistribution layer 106. In some embodiments, the encapsulant 105 laterally encapsulates the semiconductor dies 102, 104, leaving backside surfaces 102b, 104b of the semiconductor dies 102, 104 exposed. That is, a backside surface 12T of the package unit 12 is constituted by the backside surfaces 102b, 104b of the semiconductor dies 102, 104 and a backside surface 105T of the encapsulant 105. In some embodiments, the electrical connectors 109 disposed between the package unit(s) 12 and the circuit substrate 20 include or are controlled collapse chip connection (C4) bumps. In some embodiments, an underfill 107 is disposed between the package unit 12 and the circuit substrate 20 to protect the electrical connectors 109 from thermal and mechanical stresses and securing the package unit(s) 12.

Referring to FIG. 1, in some embodiments, the semiconductor dies 102, 104 are electrically connected to an interposer 108 through a redistribution layer 106. In some embodiments, the interposer 108 includes a semiconductor circuit substrate 1081 and through semiconductor vias (TSVs) 1083 for dual-side electrical connection. It is understood that the semiconductor circuit substrate 1081 may be similarly to what was previously discussed with reference to the semiconductor substrates of the semiconductor dies 102, 104. In some embodiments, the redistribution layer 106 disposed on the interposer 108 includes a dielectric layer 1061 and conductive patterns 1063 embedded therein. In some embodiments, the semiconductor dies 102, 104 are bonded to the redistribution layer 106 through micro-connectors 1045. In some embodiments, through the TSVs 1083, the semiconductor dies 102, 104 are electrically connected to the circuit substrate 20 through the electrical connectors 109 located between the interposer 108 and the circuit substrate 20. For simplicity, for the redistribution layer 106, the dielectric layer is illustrated as a single dielectric layer and the conductive patterns are illustrated as embedded in the dielectric layer, nevertheless, from the perspective of the manufacturing process, the dielectric layer may be constituted by two or more dielectric layers, and the configuration of the conductive patterns may be adjusted or modified depending on routing requirements. In some embodiments, the material of the dielectric layer 1061 includes polyimide, epoxy resin, acrylic resin, phenol resin, benzocyclobutene (BCB), polybenzooxazole (PBO), or any other suitable polymer-based dielectric material, and the dielectric layer 1061 may be formed by suitable fabrication techniques such as spin-on coating, chemical vapor deposition (CVD), lamination or the like. In some embodiments, the materials of the conductive patterns 1063 include aluminum, titanium, copper, nickel, tungsten, or alloys thereof. In some embodiments, a material of the TSVs 1083 includes one or more metal material such as copper, titanium, tungsten, aluminum, combinations thereof, or the like.

In some embodiments, the semiconductor dies 102, 104 are disposed with the active surfaces (the surfaces exposing contact pads 1043) facing the interposer 108, and the micro-connectors 1045 located there-between are or include micro-bumps or metallic pillars. In FIG. 1, in some embodiments, after the semiconductor dies 102, 104 are bonded to the redistribution layer 106, an underfill 103 is formed between the semiconductor dies 102, 104 and the redistribution layer 106 surrounding the micro-connectors 1045 to protect the micro-connectors 1045 against thermal or physical stresses and secure the electrical connection of the semiconductor dies 102, 104 to the interposer 108. In some embodiments, the underfill 103 is formed by capillary underfill filling (CUF). In some embodiments, as shown in FIG. 1, the underfill 103 is formed into multiple underfill portions with each portion respectively securing the semiconductor die 102 or 104 and the corresponding micro-connectors 1045. In some alternative embodiments, a single common underfill (not shown) may extend below the semiconductor dies 102, 104, depending on the spacing and relative positions of the dies over the interposer.

Referring to FIG. 1, an encapsulant 105 is formed over the redistribution layer 106 and the interposer 108 wrapping the semiconductor dies 102, 104 and the underfill(s) 103. In some embodiments, the encapsulant 105 includes a molding compound, a resin (such as epoxy resin or phenolic resin), or the like. In some embodiments, connective terminals 25 are formed on the circuit substrate 20 for further electrical connection. In some embodiments, the connective terminals 25 are solder balls for ball grid array mounts. In some embodiments, the connective terminals 25 are electrically connected to the package unit 12 via the circuit substrate 20.

In FIG. 1 only one package unit 12 with three semiconductor dies 102, 104 are shown on the interposer 108 for simplicity, but the disclosure is not limited thereto. Furthermore, whilst the process is currently being illustrated for a chip-on-wafer-on-substrate (CoWoS) package, the disclosure is not limited to the package structure shown in the drawings, and other types of semiconductor package such as integrated fan-out (InFO) packages, package-on-packages (PoP), etc., are also meant to be covered by the present disclosure and to fall within the scope of the appended claims.

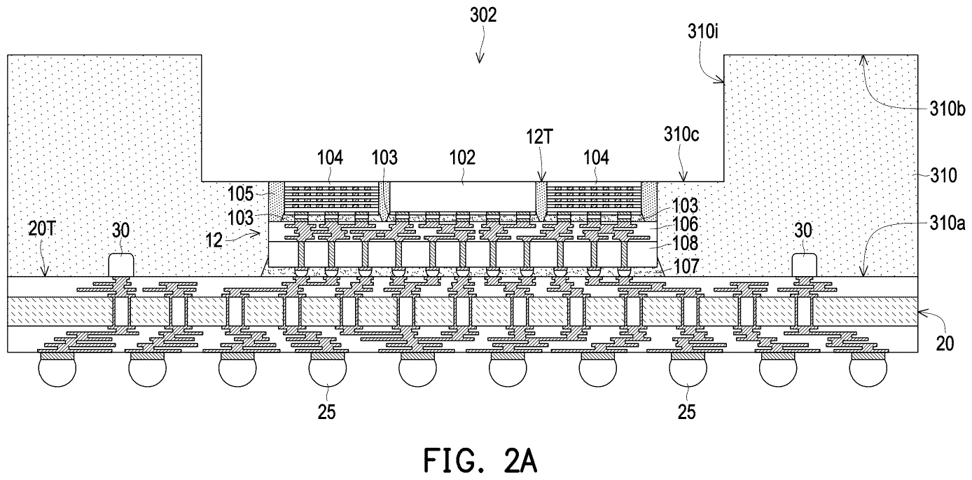

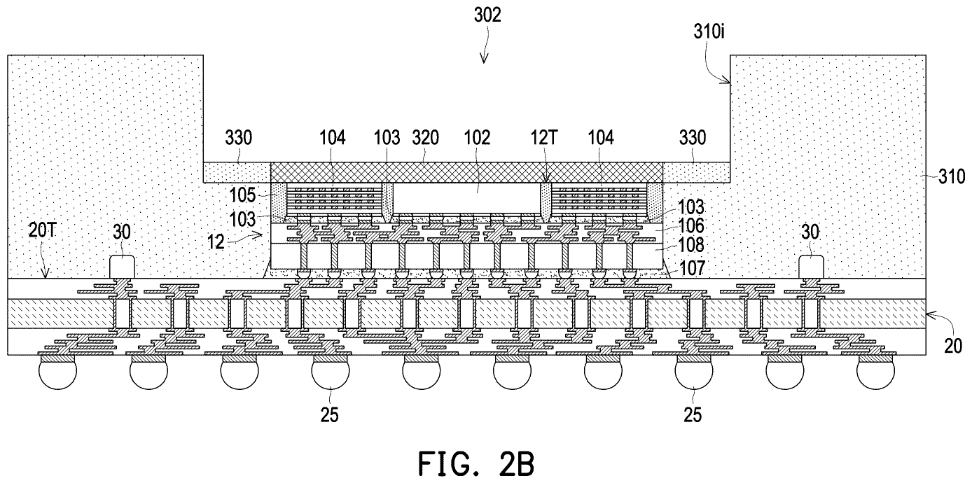

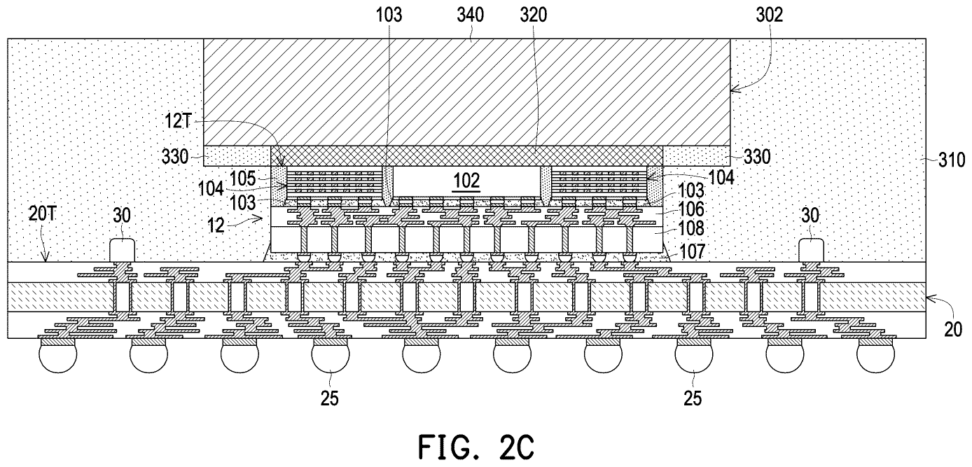

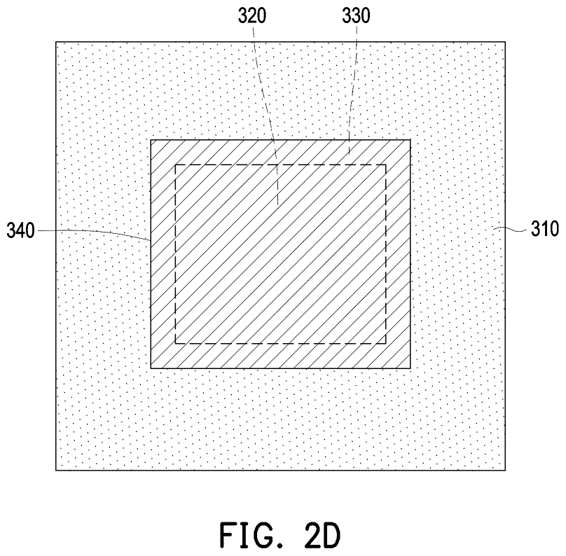

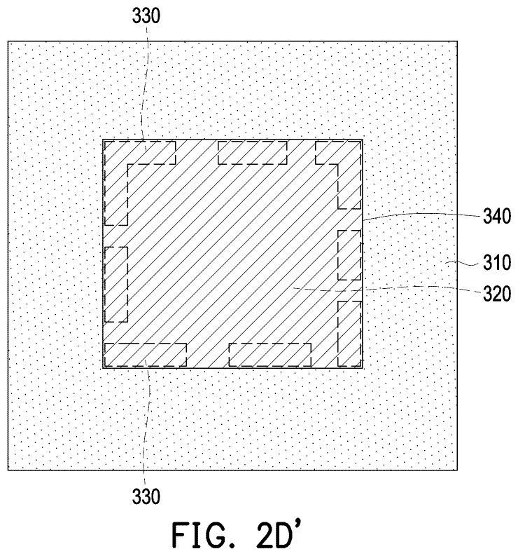

FIG. 2A through FIG. 2D′ are schematic cross-sectional views and top views schematically illustrate various stages of a process for fabricating a package structure in accordance with some embodiments of the present disclosure.

Referring to FIG. 2A, in some embodiments, a molding layer 310 is formed over the top surface 20T of the circuit substrate 20 within a recess 302, and encapsulates the package unit 12 and the passive components 30. The molding layer 310 includes a first surface 310a disposed on the top surface 20T of the circuit substrate 20, and a second surface 310b opposite to the first surface 310a and facing away from the top surface 20T of the circuit substrate 20. The backside surface 12T of the package unit 12 is revealed from a bottom surface 310c of the recess 302 of the molding layer 310. The bottom surface is levelled with the backside surface 12T of the package unit 12. Inner sidewalls 310i of the molding layer 310 extend from the first surface 310a of the molding layer 310 to the bottom surface 310c of the recess 302. A space between the inner sidewalls 310i of the molding layer 310 is the recess 302. A lateral dimension of the recess 302 is greater than a lateral dimension of the package unit 12.

The formation of the molding layer 310 at least laterally wrapping the package unit 12, fully covering the sidewalls of the package unit 12 and the underfill 107, which effectively relieves the stress of the package unit and prevents underfill delamination within the package unit 12 and between the package unit 12 and the circuit substrate 20.

A level of the bottom surface 310c of the molding layer 310 is between a level of the first surface 301a of the molding layer 310 and a level of the second surface 310b of the molding layer 310. In some embodiments, a thickness of the molding layer 310 from the first surface 301a to the second surface 310b is in a range of about 500 μm to 5000 μm. For example, a thickness of the molding layer 310 from the first surface 301a to the second surface 310b is in a range of about 1000 μm to 4000 μm (such as 2000 μm to 3000 μm). In some embodiments, a thickness of the molding layer 310 from the bottom surface 310c of the recess 302 to the second surface 310b is in a range of about 800 μm to 1200 μm.

In some embodiments, the molding layer 310 is formed by molding such as transfer molding, injection molding, compression molding or over-molding. In one embodiment, the molding layer 310 is formed by a transfer molding process with a portion of a mold chase (not shown) in direct contact with the backside surface 12T of the package unit 12 so that the molding layer 310 is formed with the recess 302 to reveal the backside surface 12T of the package unit 12 after demolding. In some embodiments, the material of the molding layer 310 includes a resin such as an epoxy resin, a phenolic resin, a thermosetting resin material or a molding underfill (MUF). In some embodiments, the underfill 103 may be replaced with the MUF, and the MUF spread in a space between the semiconductor dies 102, 104 and the redistribution layer 106 and laterally encapsulates the semiconductor dies 102, 104 and surrounds the micro-connectors 1045.

Referring to FIG. 2B, in some embodiments, a thermal interface material (TIM) 320 is disposed on the backside surface 12T of the package unit 12 within the recess 302, and an adhesive 330 is also disposed on the bottom surface 310c of the recess 302 of the molding layer 310. The adhesive 330 is disposed beside the TIM 320 and is in direct contact with the molding layer 310 and the TIM 320. In some embodiments, the TIM 320 and the adhesive 330 together fully occupies the whole bottom surface of the recess 302 of the molding layer 310. The TIM 320 is in contact with the backside surfaces 102b, 104b of the semiconductor dies 102, 104 and the backside surface 105T of the encapsulant 105.

In some embodiments, the TIM 320 includes or is a solid type metal-TIM, a liquid type metal-TIM, a gel-type TIM (containing polymer base materials) or a film-type TIM (containing polymer base materials). In some embodiments, the TIM 320 includes one or more metals from tin (Sn), gallium (Ga), indium (In), bismuth (Bi), zinc (Zn), silver (Ag) or other suitable thermally conductive metals. In some embodiments, the TIM 320 includes gallium, gallium alloys, gallium-indium-tin alloys, gallium-indium-tin-zinc alloys, indium-bismuth-tin alloys. According to the type of material used, the TIM 320 may be formed by deposition, lamination, printing, plating, or any other suitable technique. In some embodiments, the TIM 320 disposed on the backside surface 12T of the package unit 12 further improves heat dissipation. In some embodiments, a thermal conductivity of the TIM 320 is in a range from about 1 W/mK to 100 W/mK, for example more than 10 W/mK. In some embodiments, a thickness of the TIM 320 is in a range of about 50 μm to 300 μm.

In some embodiments, the adhesive 330 is formed before applying the TIM 320 and may function as a dam or spacer to limit the spreading of the TIM 320. As seen in FIG. 2B, the adhesive 330 is disposed on the bottom surface 310c of the recess 302 of the molding layer 310, beside the TIM 320 and encloses the TIM 320 from a top view. In some embodiments, the adhesive 330 is formed into a continuous frame from a top view of FIG. 2D, and the adhesive 330 is in contact with the inner sidewalls 310i, and the TIM 320 that is surrounded by the adhesive 330 is not in contact with inner sidewalls 310i. In some embodiments, the adhesive 330 on the bottom surface 310c of the recess 302 of the molding layer 310 is formed into multiple portions spaced apart from each other, arranged as a frame but with gaps there-between, and the TIM 320 is formed in the gaps between the multiple portions, so that both of the adhesive 330 and the TIM 320 are in contact with the inner sidewalls 310i of the molding layer 310 as seen in FIG. 2D′. In some embodiments, the adhesive 330 is sandwiched between the TIM 320 and the molding layer 310

In some embodiments, the material of the adhesive 330 are independently selected from a thermo-curable adhesive, a photocurable adhesive, a thermally conductive adhesive, a thermosetting resin, a waterproof adhesive, a lamination adhesive, or a combination thereof. According to the type of material(s) used, the adhesive 330 may be formed by dispensing, lamination, printing, or any other suitable technique. In some embodiments, the TIM 320 is formed on the backside surface 12T of the package unit 12, then the adhesive 330 is formed on the molding layer 310. In some embodiments, the adhesive 330 is formed on the molding layer 310, then the TIM 320 is formed on the backside surface 12T of the package unit 12.

Referring to FIG. 2C, in some embodiments, a lid 340 is disposed on the adhesive 330 and the TIM 320 within the recess 302 of the molding layer 310. In some embodiments, after mounting the lid 340 to the molding layer 310, a thermal process or a pre-curing process is performed so that the lid 340 is fixed to the molding layer 310 through the adhesive 330. In some embodiments, the lid 340 is adhered to the molding layer 310 and the package unit 12 through the adhesive 330 and the TIM 320. In some embodiments, a lateral dimension of the lid 340 is larger than a lateral dimension of the package unit 12. In some embodiments, a thickness of the lid 340 is in a range of about 1300 μm to 5000 μm.

In some embodiments, the molding layer 310 (as a stress buffer layer) surrounding the package unit 12 and the lid 340 effectively reduces the stress of the package structure. In some embodiments, the lid and the molding layer 310 disposed on the circuit substrate 20 together counterbalance and lessen the warpage of the package structure, and the molding layer 310 also functions as a warpage compensation layer. In some embodiments, the formation of the adhesive 330 and the molding layer 310 further defines the spreading of the TIM 320 and both may function as the dam to prevent the outflow or over spreading of the TIM 320. Through such arrangement of the TIM 320, the molding layer 310 and the lid 340, the reliability and yield of the package structure are improved as the package structure is formed with less warpage and stress.

Referring to FIG. 2D, FIG. 2D is a top view of FIG. 2C. In some embodiments, the lid 340 is encircled by the molding layer 310 and its top surface is revealed from the molding layer 310. In some embodiments, the molding layer 310 encloses the profile of the periphery of the lid 340. In some embodiments, a lateral dimension of the lid 340 is less than lateral dimensions of the molding layer 310 and the circuit substrate 20. In other embodiments, referring to FIG. 2D′, the lid 340 is disposed on the adhesive 330 and the TIM 320 in contact with the inner sidewalls 310i of the molding layer 310.

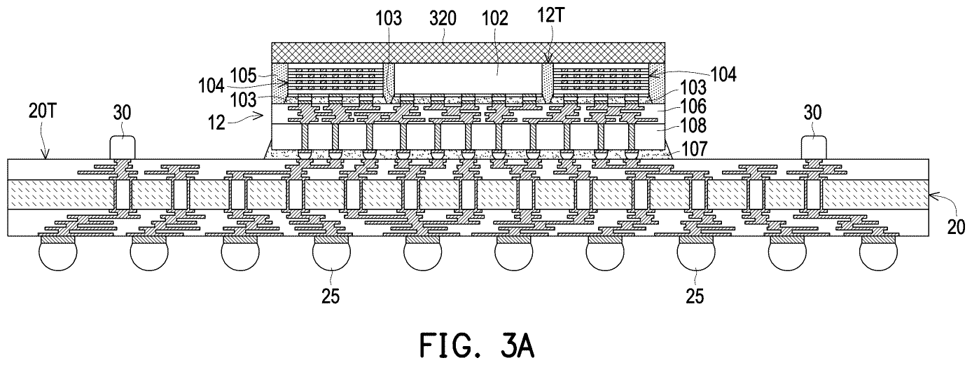

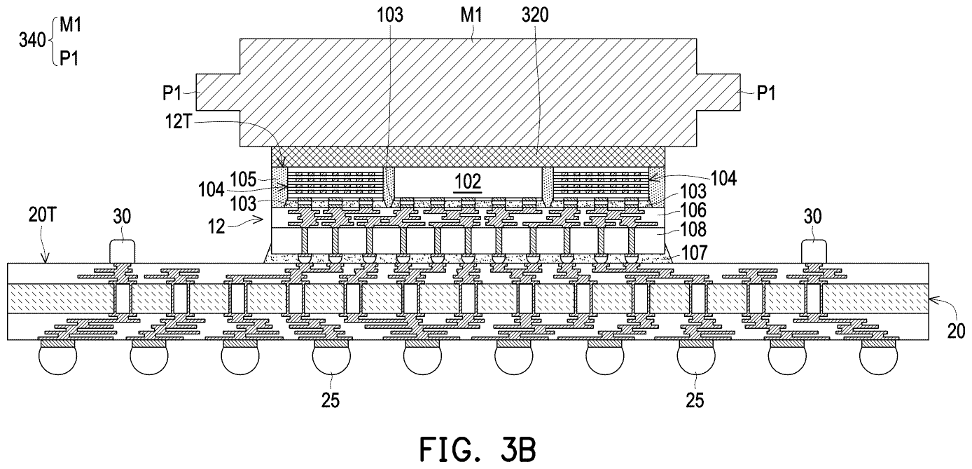

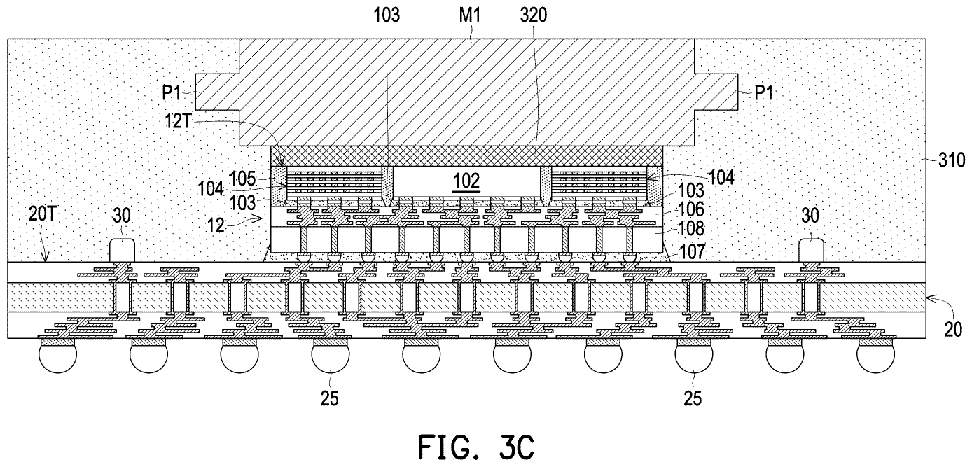

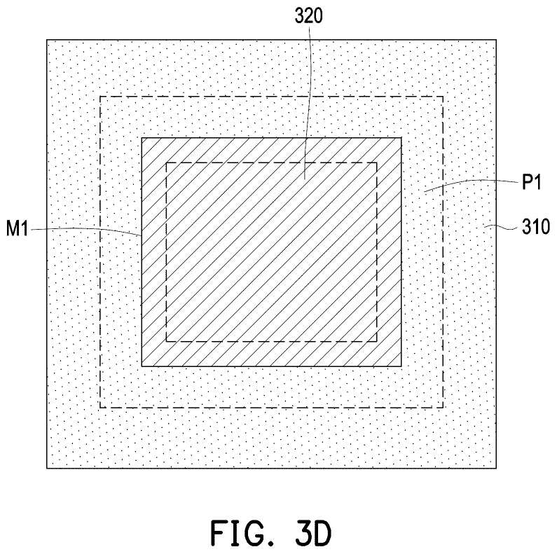

FIG. 3A through FIG. 3D are schematic cross-sectional views and top views schematically illustrate various stages of a process for fabricating a package structure in accordance with some embodiments of the present disclosure. Except for the further description, the definition of the reference symbols and labeled representations are the same as FIG. 1 and FIG. 2A through FIG. 2D′, and will not be repeated herein.

Referring to FIG. 3A, in some embodiments, the TIM 320 is disposed on the backside surface 12T of the package unit 12 before the molding layer 310 is formed. The TIM 320 is in contact with the backside surfaces 102b, 104b of the semiconductor dies 102, 104 and the backside surface 105T of the encapsulant 105.

Referring to FIG. 3B, in some embodiments, the lid 340 with a protrusion P1 is disposed on the TIM 320. The lid 340 includes a main portion M1 disposed on the TIM 320 and the protrusion P1 laterally protruding from sidewalls of the main portion M1. In some embodiments, the protrusion P1 laterally protrudes from sidewalls of the main portion M1 and a bottom surface of the protrusion P1 is levelled with a bottom surface of the main portion M1. In some embodiments, the protrusion P1 laterally protrudes from sidewalls of the main portion M1 and a top surface of the protrusion P1 is levelled with a top surface of the main portion M1. In some embodiments, the main portion M1 is enclosed by the protrusion P1 from a top view. In some embodiments, a lateral dimension of the protrusion P1 is larger than lateral dimensions of top and bottom surfaces of the main portion M1.

Referring to FIG. 3C, in some embodiments, the molding layer 310 is formed over the top surface 20T of the circuit substrate 20, and laterally encapsulates and surrounds the package unit 12, the TIM 320, the lid 340 and the passive components 30. In the embodiment, the molding layer 310 is in contact with the TIM 320. In the embodiment, the molding layer 310 laterally encapsulates the main portion M1 and the protrusion P1 of the lid 340. In the embodiment, the molding layer 310 laterally encapsulates the lid 340 with a larger contact area to improve an adhesion between the lid 340 and the molding layer 310.

Referring to FIG. 3D, FIG. 3D is a top view of FIG. 3C. In some embodiments, the lid 340 is enclosed by the molding layer 310 and revealed from the molding layer 310. In some embodiments, the main portion M1 of the lid 340 encloses the protrusion P1 of the lid 340. In some embodiments, the protrusion P1 of the lid 340 is embedded in the molding layer 310. In some embodiments, a lateral dimensions of the main portion M1 is less than a lateral dimensions of the protrusion P1. In some embodiments, the lateral dimensions of the main portion M1 and the protrusion P1 of the lid 340 are less than lateral dimensions of the molding layer 310 and the circuit substrate 20.

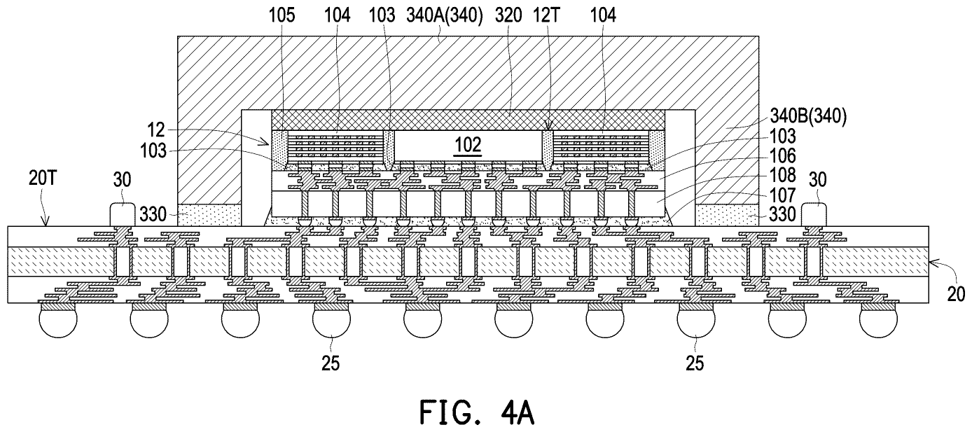

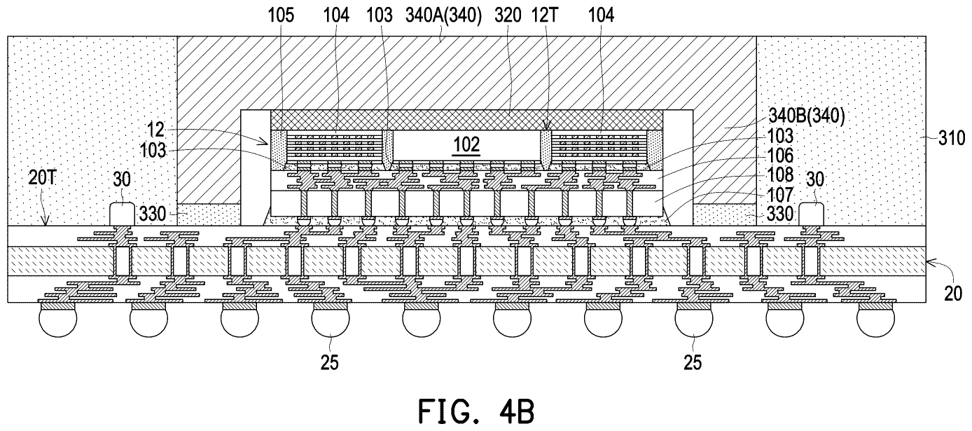

FIG. 4A to FIG. 4B are schematic cross-sectional views schematically illustrate various stages of a process for fabricating a package structure in accordance with some embodiments of the present disclosure. Except for the further description, the definition of the reference symbols and labeled representations are the same as FIG. 1 and FIG. 2A through FIG. 2D′, and will not be repeated herein.

Referring to FIG. 4A, in some embodiments, the TIM 320 is disposed on the backside surface 12T of the package unit 12, the adhesive 330 is disposed on the top surface 20T of the circuit substrate 20, and the lid 340 is disposed on the adhesive 330 and the TIM 320. In some embodiments, the lid 340 is adhered to the circuit substrate 20 and the package unit 12 through the adhesive 330 and the TIM 320.

In some embodiments, the lid 340 includes a horizontal portion 340A extending on the TIM 320 and the package unit 12, and a vertical portion 340B joined with the horizontal portion 340A and surrounding the horizontal portion 340A. In some embodiments, the horizontal portion 340A is disposed directly on the TIM 320 and fully covers the TIM 320 and extends substantially parallel to the circuit substrate 20. In some embodiments, the vertical portion 340B extends in a direction substantially perpendicular to the plane defined by the horizontal portion 340A. In some embodiments, the horizontal portion 340A and the vertical portion 340B are integrally formed (i.e. jointed to each other without a clear interface between the two). In some embodiments, the vertical portion 340B of the lid 340 is adhered to the circuit substrate 20 through the adhesive 330, and the horizontal portion 340A of the lid 340 is adhered to the package unit 12 thorough the TIM 320. In one embodiment, the vertical portion 340B may be shaped as a ring wall, and when the lid is placed over the package unit 12, the vertical portion 340B encircles the package unit 12 but is spaced apart from the package unit 12 with a void space there-between.

In some embodiments, the dimensions or the span of the horizontal portion 340A is larger than that of the package unit 12 but smaller than the span of the circuit substrate 20 or a sub-unit of the circuit substrate 20, leaving rooms for the molding layer 310. Although a lateral dimension of the TIM 320 substantially equals to a lateral dimension of the package unit 12 shown in FIG. 4A, the lateral dimension of the TIM 320 may be slightly greater than the lateral dimension of the package unit 12 in other embodiments. In some embodiments, a thickness of a horizontal portion of the lid 340 is in a range of about 1300 μm to 5000 μm.

Referring to FIG. 4B, in some embodiments, the molding layer 310 is formed over the top surface 20T of the circuit substrate 20, and laterally encapsulates the lid 340, the adhesive 330 and the passive components 30. In some embodiments, as the vertical portion of the lid 340 landed on the circuit substrate 20 has a smaller footprint, less stress is caused between the lid 340 and the circuit substrate 20. The lid 340 together with the molding layer 310 disposed on the circuit substrate 20 work to counterbalance the warpage of the package structure.

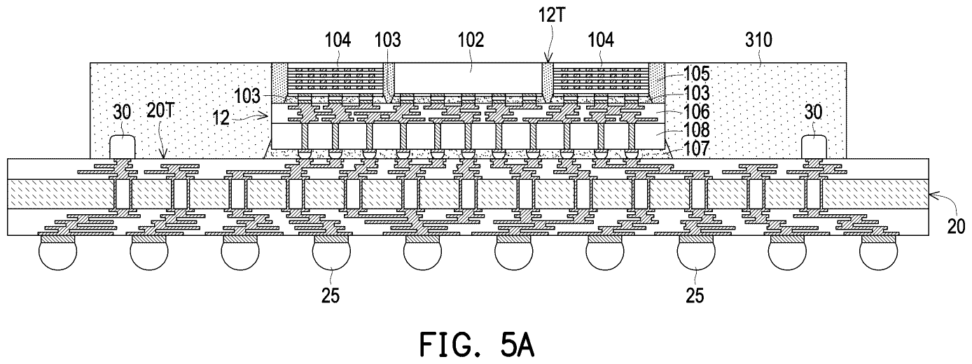

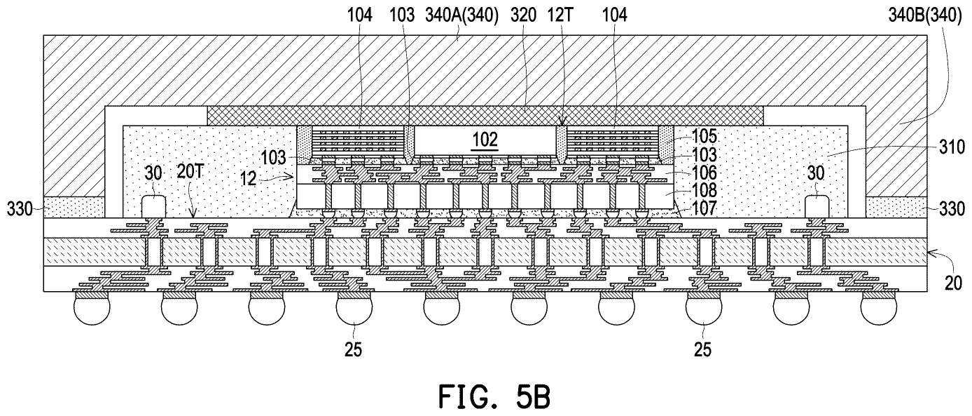

FIG. 5A to FIG. 5B are schematic cross-sectional views schematically illustrate various stages of a process for fabricating a package structure in accordance with some embodiments of the present disclosure. Except for the further description, the definition of the reference symbols and labeled representations are the same as FIG. 1, FIG. 2A through FIG. 2D′ and FIG. 4A, and will not be repeated herein.

Referring to FIG. 5A, in some embodiments, the molding layer 310 is formed over the top surface 20T of the circuit substrate 20, and laterally encapsulates the package unit 12 and the passive components 30. In some embodiments, a lateral dimension of the molding layer 310 is less than a lateral dimension of the circuit substrate 20.

Referring to FIG. 5B, in some embodiments, the TIM 320 is disposed on the backside surface 12T of the package unit 12, the adhesive 330 is disposed on the top surface 20T of the circuit substrate 20, and the lid 340 is disposed on the adhesive 330 and the TIM 320. In some embodiments, the vertical portion 340B of the lid 340 is adhered to the circuit substrate 20 through the adhesive 330, and the horizontal portion 340A of the lid 340 is adhered to the package unit 12 thorough the TIM 320. In some embodiments, a portion of the TIM 320 is disposed on the molding layer 310. In some embodiments, the vertical portion 340B of the lid 340 encloses the molding layer 310 and the TIM 320. In some embodiments, as the vertical portion of the lid 340 landed on the circuit substrate 20 has a smaller footprint, less stress is caused between the lid 340 and the circuit substrate 20. The lid 340 together with the molding layer 310 disposed on the circuit substrate 20 work to counterbalance the warpage of the package structure.

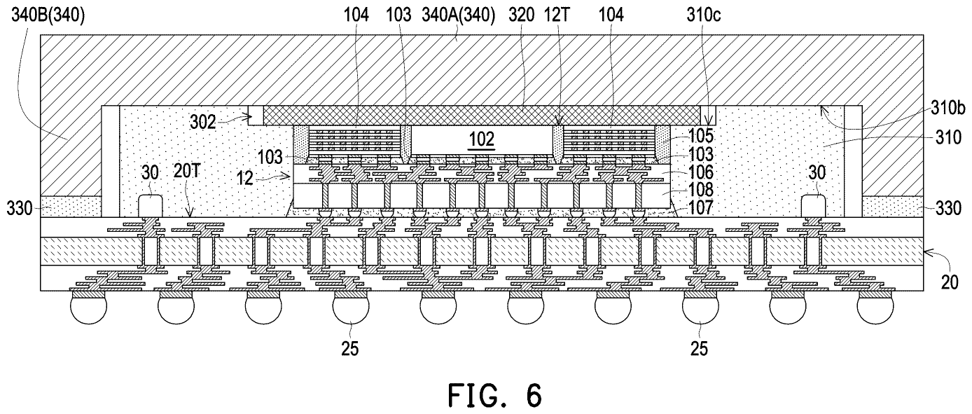

FIG. 6 to FIG. 8 illustrate schematic cross-sectional view of a package structure in accordance with some embodiments of the present disclosure. Except for the further description, the definition of the reference symbols and labeled representations are the same as FIG. 1 and FIG. 2A through FIG. 2D′, and will not be repeated herein.

Referring to FIG. 6, the difference from FIG. 5B is the TIM 320 disposed within the recess 302 of the molding layer 310, and the second surface 310b of the molding layer 310 and the TIM 320 are in contact with the lid 340. In some embodiments, the molding layer 310 encloses and laterally encapsulates the TIM 320. Although a gap laterally exists between the TIM 320 and the molding layer 310 shown in FIG. 4A, the TIM 320 may fully fill the recess 302 and in contact with the molding layer 310 in other embodiments.

In some embodiments, the TIM 320 is disposed on the backside surface 12T of the package unit 12 and the bottom surface 310c of the molding layer 310 within the recess 302 of the molding layer 310, after the molding layer 310 is formed on the circuit substrate 20. In some embodiments, the lid 340 is adhered to the circuit substrate 20 and the package unit 12 through the adhesive 330 and the TIM 320. In some embodiments, a thickness of the molding layer 310 from the bottom surface 310c of the recess 302 to the second surface 310b is in a range of about 60 μm to 500 μm. In some embodiments, the formation of the adhesive 330 and the molding layer 310 further defines the spreading of the TIM 320 and both may function as the dam to prevent the outflow or over spreading of the TIM 320

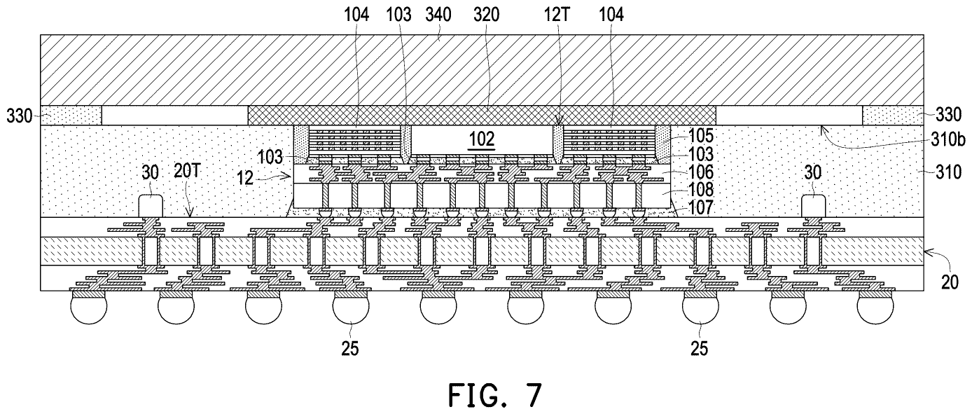

Referring to FIG. 7, the difference from FIG. 5B is the adhesive 330 disposed on the second surface 310b of the molding layer 310, and beside the TIM 320. In some embodiments, the adhesive 330 encloses and laterally encapsulates the TIM 320. Although the lid 340 having a plate shape is shown in FIG. 7, the lid 340 may include a horizontal portion extending on the TIM 320 and the package unit 12, and a vertical portion joined with the horizontal portion, surrounding the horizontal portion and adhered to the molding layer 310 through the adhesive 330 in other embodiments. In some embodiments, the lid 340 is adhered to the molding layer 310 and the package unit 12 through the adhesive 330 and the TIM 320. In some embodiments, the formation of the adhesive 330 further defines the spreading of the TIM 320 and may function as the dam to prevent the outflow or over spreading of the TIM 320.

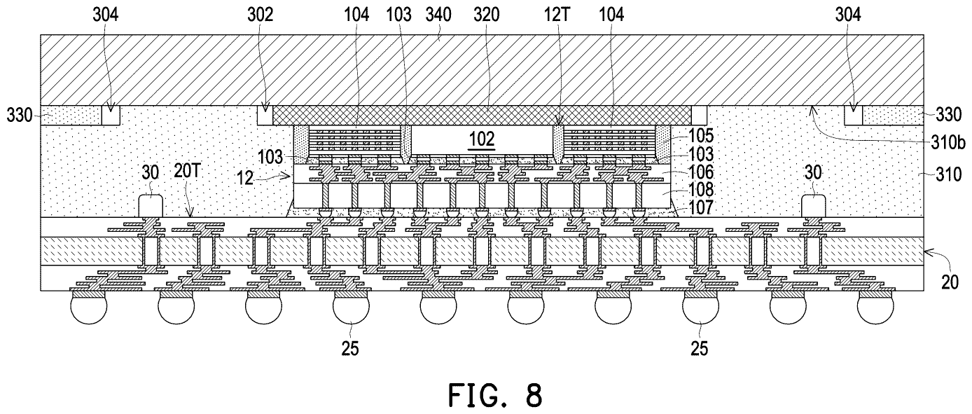

Referring to FIG. 8, the difference from FIG. 6 is the adhesive 330 disposed on the molding layer 310 within a recess 304 of the molding layer 310, and the second surface 310b of the molding layer 310 is in contact with the lid 340. In some embodiments, the recess 304 is disposed beside and encloses the recess 302 of the molding layer 310 from a top view (not shown). In some embodiments, the adhesive 330 is disposed on the molding layer 310 within a recess 304 of the molding layer 310, and encloses the TIM 320 from a top view (not shown). Although a gap laterally exists between the adhesive 330 and the molding layer 310 shown in FIG. 8, the adhesive 330 may fully fill the recess 304 and in contact with the molding layer 310 in other embodiments.

In some embodiments, the TIM 320 is disposed on the backside surface 12T of the package unit 12 within the recess 302 of the molding layer 310, after the molding layer 310 is formed on the circuit substrate 20. In some embodiments, the lid 340 is adhered to the molding layer 310 through the adhesive 330 and the TIM 320. Although the lid 340 having a plate shape is shown in FIG. 8, the lid 340 may include a horizontal portion extending on the TIM 320 and the package unit 12, and a vertical portion joined with the horizontal portion, surrounding the horizontal portion and adhered to the molding layer 310 through the adhesive 330 in other embodiments. In some embodiments, the formation of the adhesive 330 and the molding layer 310 further defines the spreading of the TIM 320 and both may function as the dam to prevent the outflow or over spreading of the TIM 320.

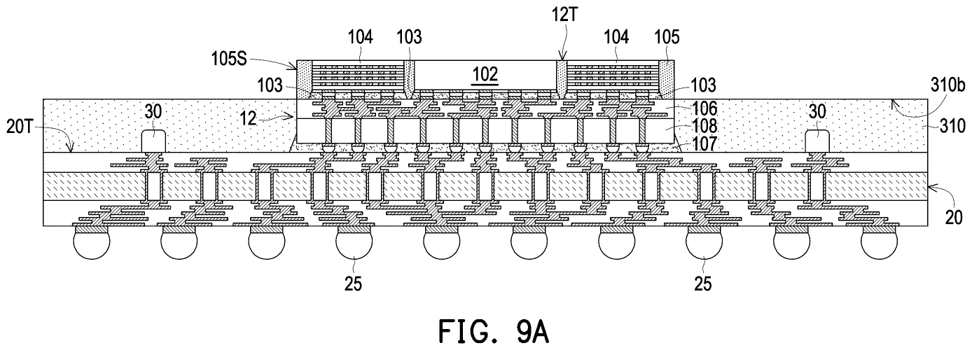

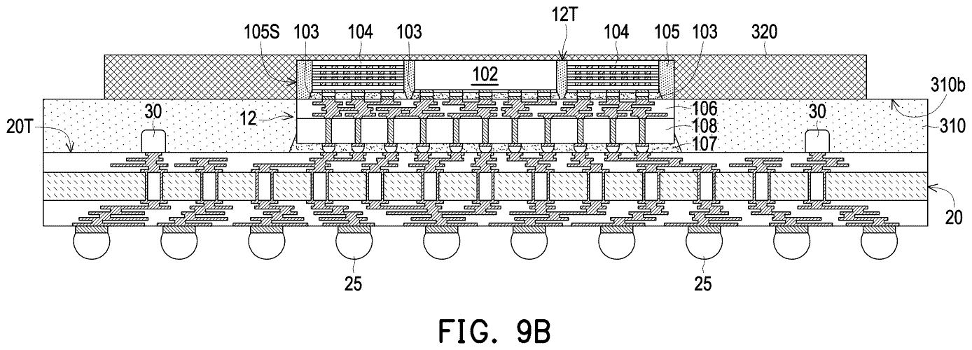

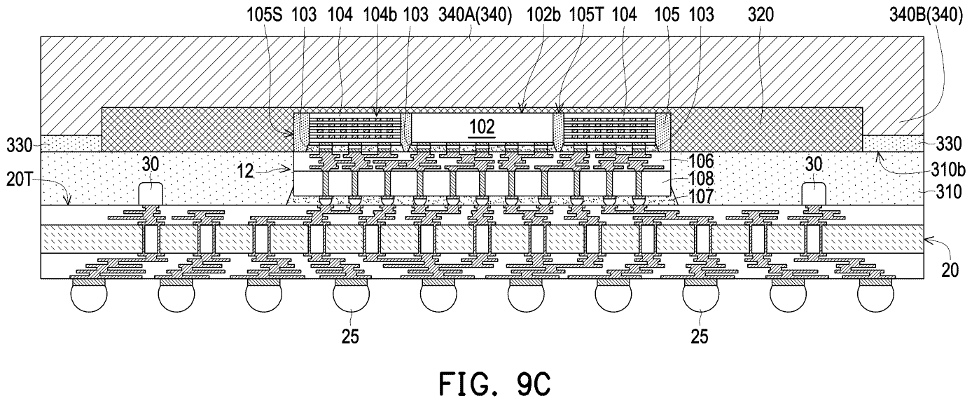

FIG. 9A through FIG. 9C are schematic cross-sectional views schematically illustrate various stages of a process for fabricating a package structure in accordance with some embodiments of the present disclosure. Except for the further description, the definition of the reference symbols and labeled representations are the same as FIG. 1 and FIG. 2A through FIG. 2D′, FIG. 5B and FIG. 7, and will not be repeated herein.

Referring to FIG. 9A, in some embodiments, the molding layer 310 is formed over the top surface 20T of the circuit substrate 20, and laterally encapsulates a portion of the package unit 12 and fully covers the passive components 30. In some embodiments, the height of the molding layer 310 may be tuned based on the product designs. For example, the molding layer 310 laterally encapsulates a portion of the package unit 12 with portions of the sidewalls 105S of the encapsulant 105 are revealed and the backside surface 12T of the package unit 12 is revealed.

In some embodiments, the molding layer 310 laterally encapsulates the underfill 107 and the interposer 108 of the package unit 12, and sidewalls of the redistribution layer 106 and the encapsulant 105 of the package unit 12 are revealed. In some embodiments, the molding layer 310 laterally encapsulates the underfill 107, the interposer 108 and the redistribution layer 106 of the package unit 12, and sidewalls 105S of the encapsulant 105 of the package unit 12 are revealed.

Referring to FIG. 9B, in some embodiments, the TIM 320 is disposed on the backside surface 12T of the package unit 12, sidewalls of the package unit 12 (for example, sidewalls 105S of the encapsulant 105 of the package unit 12), and the second surface 310b of the molding layer 310. In some embodiments, the TIM 320 encloses the sidewalls 105S of the encapsulant 105 of the package unit 12, and extends over the backside surface 12T of the package unit 12 and the second surface 310b of the molding layer 310.

Referring to FIG. 9C, in some embodiments, the adhesive 330 is disposed on the second surface 310b of the molding layer 310, and the lid 340 is disposed on the adhesive 330 and the TIM 320. In some embodiments, the adhesive 330 is disposed on the second surface 310b of the molding layer 310, and beside the TIM 320. In some embodiments, the adhesive 330 encloses and laterally encapsulates the TIM 320. In some embodiments, the lid 340 is adhered to the molding layer 310 and the package unit 12 through the adhesive 330 and the TIM 320. In some embodiments, the TIM 320 is disposed between the lid 340 and the package unit 12 and between the lid 340 and the molding layer 310.

In some embodiments, the formation of the adhesive 330 further defines the spreading of the TIM 320 and may function as the dam to prevent the outflow or over spreading of the TIM 320. the molding layer 310 (as a stress buffer layer) surrounding the package unit 12 and the lid 340 effectively reduces the stress of the package structure. In some embodiments, the lid and the molding layer 310 disposed on the circuit substrate 20 together counterbalance and lessen together counterbalance and lessen the warpage of the package structure. In some embodiments, the package structure simultaneously balances the warpage of the package structure, and the molding layer 310 also functions as a warpage compensation layer. In some embodiments, the TIM 320 disposed on the backside surfaces 102b, 104b of the semiconductor dies 102, 104, and the backside surface 105T and the sidewalls 105S of the encapsulant 105 are beneficial for heat transfer from the backside surfaces 102b, 104b of the semiconductor dies 102, 104, and the backside surface 105T and the sidewalls 105S of the encapsulant 105.

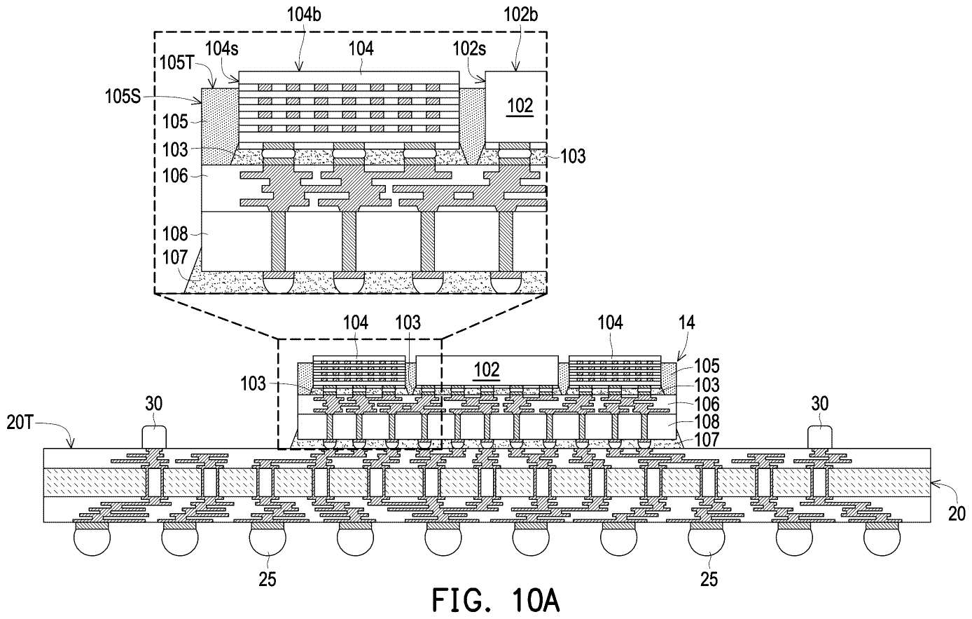

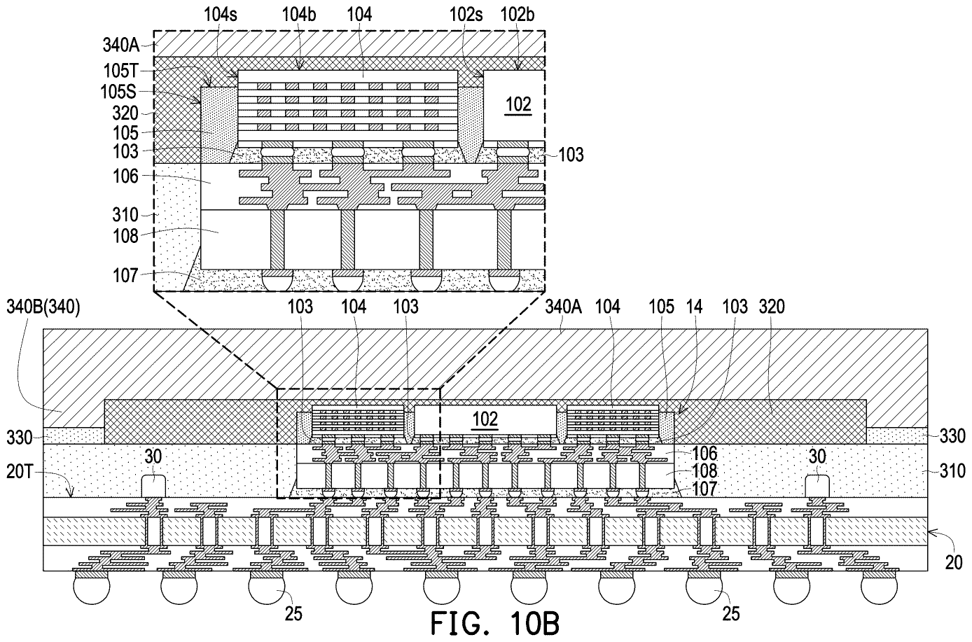

FIG. 10A to FIG. 10B are schematic cross-sectional views schematically illustrate various stages of a process for fabricating a package structure in accordance with some embodiments of the present disclosure.

Referring to FIG. 10A, the difference from FIG. 9A is a package unit 14 disposed on the circuit substrate 20. In some embodiments, in the package unit 14, partial sidewalls 102s, 104s of the semiconductor dies 102, 104 is revealed by removing a portion of the encapsulant 105. In some embodiments, the encapsulant 105 laterally encapsulates partial sidewalls 102s, 104s of the semiconductor dies 102, 104. In some embodiments, the backside surface 105T of the encapsulant 105 misaligns with the backside surfaces 102b, 104b of the semiconductor dies 102, 104. In some embodiments, the backside surface 105T of the encapsulant 105 is lower than the backside surfaces 102b, 104b of the semiconductor dies 102, 104. In some embodiments, an etching process is preformed to remove the portion of the encapsulant 105. For example, the etching process is a plasma etching process, a wet etching process, or any suitable process. In some embodiments, a thickness of the removed portion of the encapsulant 105 is in a range of about 10 μm to 500 μm, for example about 50 μm.

Referring to FIG. 10B, in some embodiments, the molding layer 310 laterally encapsulates the package unit 14, and the TIM 320 is disposed on the second surface 310b of the molding layer 310 and the package unit 14. In some embodiments, the TIM 320 covers the backside surfaces 102b, 104b and sidewalls 102s, 104s of the semiconductor dies 102, 104, and the backside surface 105T and the sidewalls 105S of the encapsulant 105.

In some embodiments, the adhesive 330 encloses and laterally wraps the TIM 320. In some embodiments, the lid 340 is adhered to the molding layer 310 and the package unit 14 through the adhesive 330 and the TIM 320. In some embodiments, the TIM 320 is disposed between the lid 340 and the package unit 14 and between the lid 340 and the molding layer 310.

In some embodiments, the TIM 320 disposed on the backside surfaces 102b, 104b and sidewalls 102s, 104s of the semiconductor dies 102, 104, and the backside surface 105T and the sidewalls 105S of the encapsulant 105 are beneficial for heat transfer from the backside surfaces 102b, 104b and sidewalls 102s, 104s of the semiconductor dies 102, 104, and the backside surface 105T and the sidewalls 105S of the encapsulant 105.

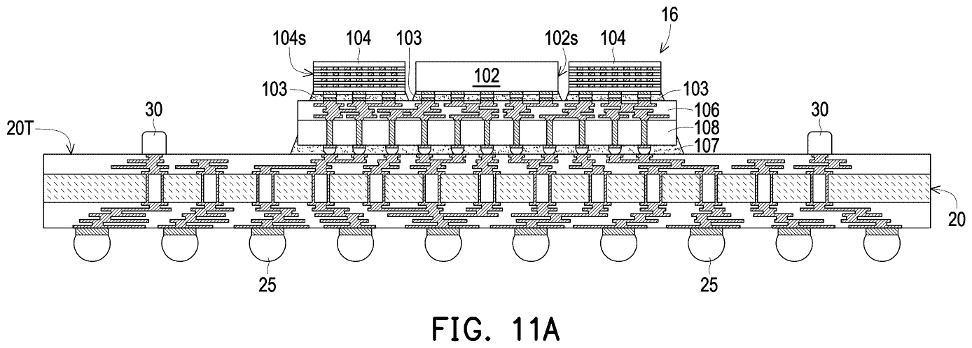

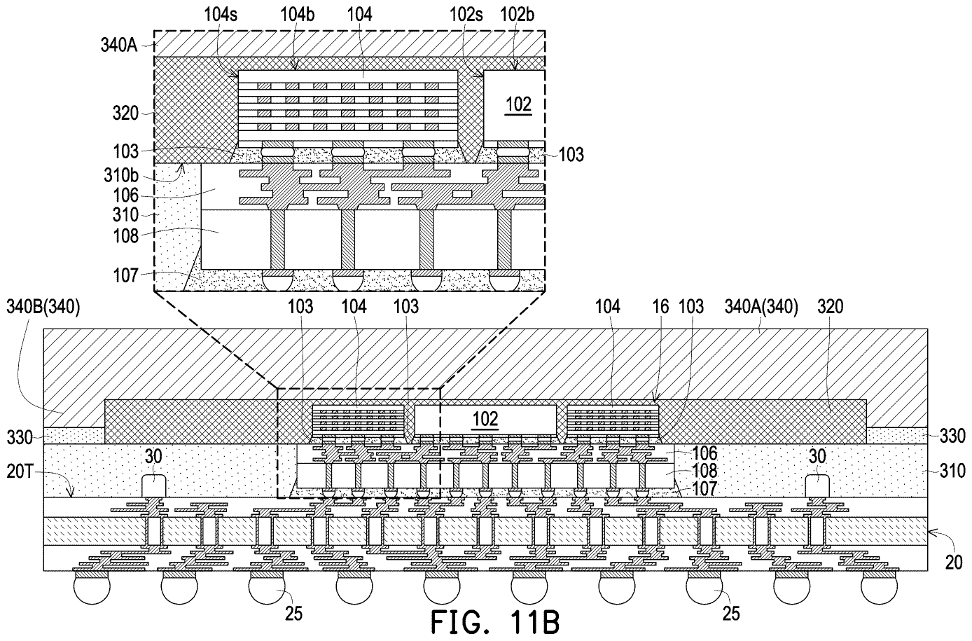

FIG. 11A to FIG. 11B are schematic cross-sectional views schematically illustrate various stages of a process for fabricating a package structure in accordance with some embodiments of the present disclosure.

Referring to FIG. 11A, the difference from FIG. 10A is a package unit 16 disposed on the circuit substrate 20. In some embodiments, in the package unit 16, the whole sidewalls 102s, 104s of the semiconductor dies 102, 104 and the underfill 103 are revealed. That is, the whole sidewalls 102s, 104s of the semiconductor dies 102, 104 and the underfill 103 are not encapsulated by the encapsulant 105.

Referring to FIG. 11B, in some embodiments, the molding layer 310 laterally encapsulates the package unit 16, and the TIM 320 is disposed on the second surface 310b of the molding layer 310 and the package unit 16. In some embodiments, the TIM 320 covers the backside surfaces 102b, 104b and sidewalls 102s, 104s of the semiconductor dies 102, 104, and covers the underfill 103 and the second surface 310b of the molding layer 310.

In some embodiments, the adhesive 330 encloses and laterally wraps the TIM 320. In some embodiments, the lid 340 is adhered to the molding layer 310 and the package unit 16 through the adhesive 330 and the TIM 320. In some embodiments, the TIM 320 is disposed between the lid 340 and the package unit 16 and between the lid 340 and the molding layer 310. In some embodiments, the TIM 320 disposed on the backside surfaces 102b, 104b and sidewalls 102s, 104s of the semiconductor dies 102, 104 are beneficial for heat transfer from the backside surfaces 102b, 104b and sidewalls 102s, 104s of the semiconductor dies 102, 104.

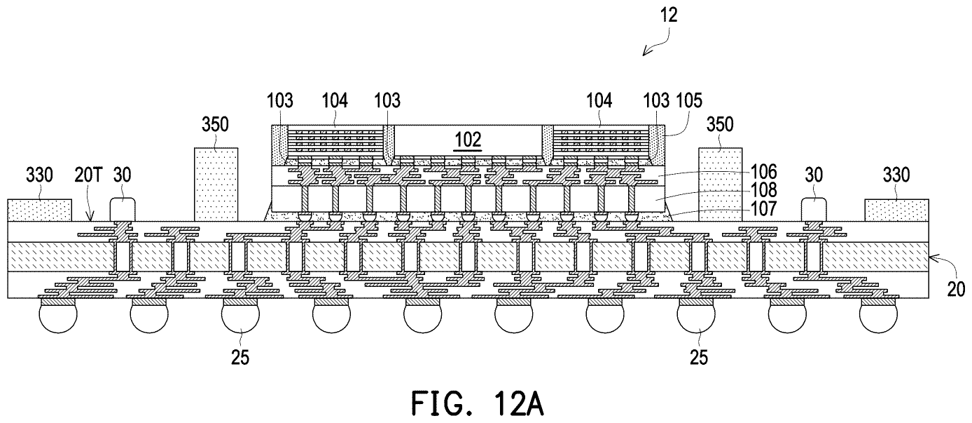

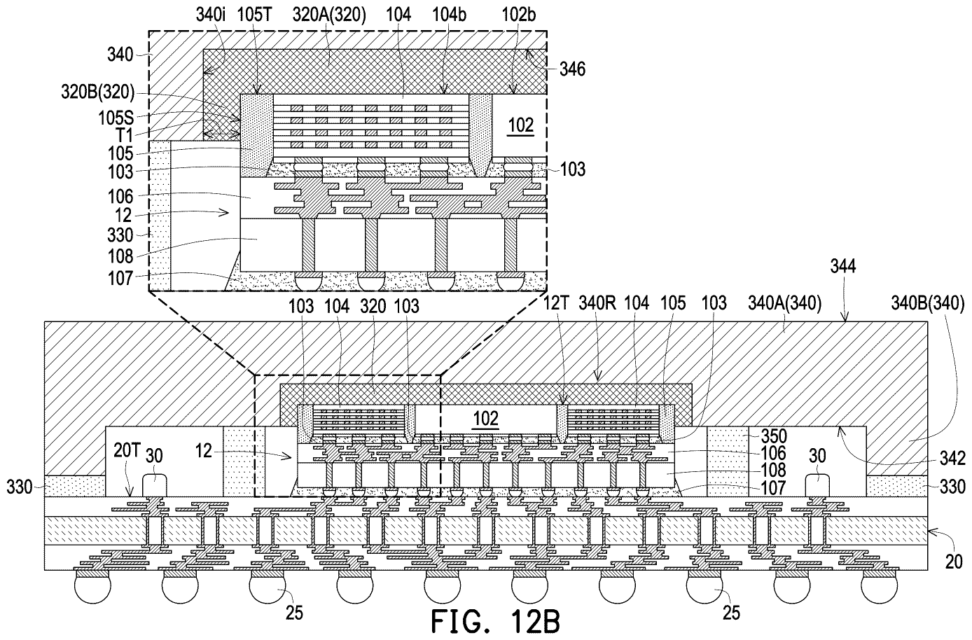

FIG. 12A to FIG. 12B are schematic cross-sectional views schematically illustrate various stages of a process for fabricating a package structure in accordance with some embodiments of the present disclosure. Except for the further description, the definition of the reference symbols and labeled representations are the same as FIG. 1, and will not be repeated herein.

Referring to FIG. 12A, in some embodiments, a dam 350 and the adhesive 330 are formed on the circuit substrate 20 before mounting the lid. In some embodiments, the dam 350 is or includes a dam structure surrounding the package unit 12, and may be referred to as a molding dam or an adhesive dam. For example, the material(s) and formation method of the dam 350 are similar as adhesive 330 or the same as the molding layer 310 described in the previous contexts. In some embodiments, the dam 350 is disposed between the package unit 12 and the passive components 30. In some embodiments, the dam 350 is formed on the top surface 20T of the circuit substrate 20 and encloses the package unit 12. In some embodiments, the dam 350 has a height lower than the package unit 12. In some embodiments, the dam 350 forms a continuous frame wall enclosing the package unit 12 and the TIM 320 and spaced apart from the package unit 12. The dam 350 may function to limit the distribution and span of the to-be-formed TIM 320. Also, the dam 350 located between the package unit 12 and the passive components 30 and in contact with the lid 340 and the circuit substrate 20 physically isolate the package unit 12 and the passive components 30. In some embodiments, the adhesive 330 encloses the dam 350.

The dam 350 is disposed aside and spaced apart from the package unit 12 with a distance and the dam 350 that is made of an insulative dielectric material functions as a blockage dam for preventing the outflow of the TIM 320 In some embodiments, the dam 350 and the adhesive 330 are formed from the same adhesive material and formed from the same dispensing process. In some embodiments, the dam 350 and the adhesive 330 are formed from different adhesive materials. For example, the material of the dam 350 and the material of the adhesive 330 are independently selected from a thermo-curable adhesive, a photocurable adhesive, a thermally conductive adhesive, a thermosetting resin, a waterproof adhesive, a lamination adhesive, or a combination thereof. In some embodiments, the dam 350 is made from a polymeric dielectric material such as epoxy resins, silicon-containing resins or acrylic resins. In some embodiments, the dam 350 includes an epoxy resin, and the adhesive 330 includes a thermally conductive adhesive. According to the type of material(s) used, the dam 350 or adhesive 330 may be formed by dispensing, lamination, printing, or any other suitable technique.

Referring to FIG. 12B, in some embodiments, the TIM 320 is disposed within a lid recess 340R of the lid 340, and the lid 340 is adhered to the circuit substrate 20 and the package unit 12 through the adhesive 330, the dam 350, and the TIM 320. In some embodiments, the lid 340 includes a horizontal portion 340A extending on the TIM 320 and the package unit 12, and a vertical portion 340B joined with the horizontal portion 340A and surrounding the horizontal portion 340A. In some embodiments, the dam 350 is in contact with the horizontal portion 340A of the lid 340. In some embodiments, the horizontal portion 340A of the lid 340 comprises a first surface 342 disposed on the dam 350, a second surface 344 opposite to the first surface 342, and the lid recess 340R including a bottom surface 346 between the first surface 342 and the second surface 344. In some embodiments, the TIM 320 covers the bottom surface 346 and sidewalls 340i of the lid recess 340R. In some embodiments, the TIM 320 fills the lid recess 340R of the lid 340, covers the backside surfaces 102b, 104b of the semiconductor dies 102, 104, and covers the sidewalls 105S and the backside surface 105T of the encapsulant 105.

In some embodiments, the TIM 320 includes a base portion 320A and an extended portion 320B joined with the base portion 320A and surrounding the base portion 320A. In some embodiments, the extended portion 320B projects downward from the base portion 320A, as seen in FIG. 12B. In some embodiments, the base portion 320A is disposed directly on the backside surface 12T and fully cover the backside surface 12T of the package unit 12 and extend substantially parallel to the circuit substrate 20. In some embodiments, the extended portion 320B extend in a direction substantially perpendicular to the plane defined by the base portion 320A. In some embodiments, a thickness T1 of the extended portion 320B between the sidewalls 340i of the lid recess 340R and the sidewalls of the package unit 12 is in a range of about greater than 100 μm.

In some embodiments, the TIM 320 is formed into a reverse basin shaped or reverse bowl-shaped structure. In some embodiments, the extended portion 320B is in contact with the sidewalls of the package unit 12, and covers portions of the sidewalls of the package unit 12. In some embodiments, the extended portion 320B of the TIM 320 is in direct contact with and sandwiched between the lid 340 and the sidewalls 105S of the encapsulant 105.

Although the extended portion 320B covers the sidewalls 105S of the encapsulant 105 in FIG. 12B, the extended portion 320B fully covers the sidewalls 105S of the encapsulant 105 in other embodiments. In some embodiments, the extended portion 320B covers the sidewalls 105S of the encapsulant 105, and the sidewalls of the redistribution layer 106. In some embodiments, the extended portion 320B covers the sidewalls 105S of the encapsulant 105, and the sidewalls of the redistribution layer 106 and the interposer 108. In some embodiments, the extended portion 320B covers the sidewalls 105S of the encapsulant 105, covers the sidewalls of the redistribution layer 106, the interposer 108 and the underfill 107, and extend to the top surface 20T of the circuit substrate 20.

In some embodiments, the dam 350 encloses the package unit 12 and the TIM 320, and the dam 350 located between the TIM 320 covering the package unit 12 and the passive components 30 physically isolate the TIM 320 and the passive components 30. In some embodiments, the formation of the dam 350 further defines the spreading of the TIM 320 and may function as the dam to prevent the outflow or over spreading of the TIM 320. In some embodiments, the TIM 320 disposed on the backside surfaces 102b, 104b of the semiconductor dies 102, 104, and the backside surface 105T and the sidewalls 105S of the encapsulant 105 are beneficial for heat transfer.

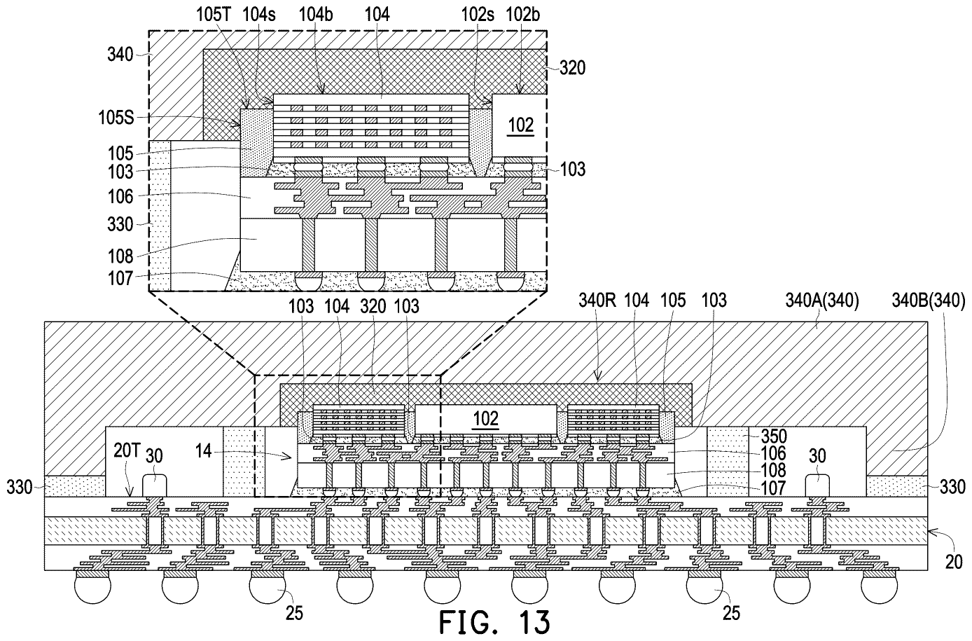

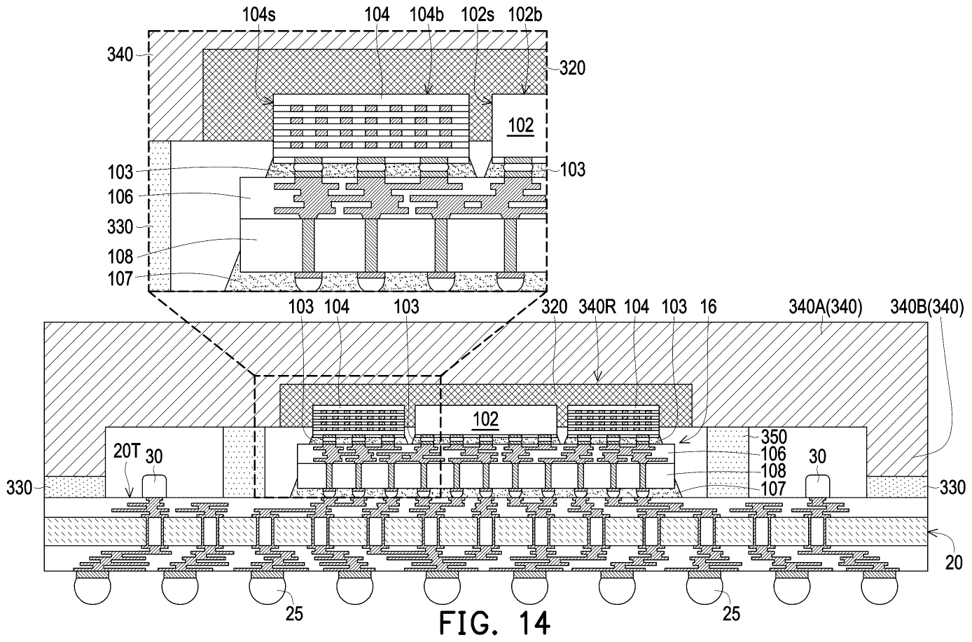

FIG. 13 to FIG. 14 illustrate schematic cross-sectional view of a package structure in accordance with some embodiments of the present disclosure.

Referring to FIG. 13, in some embodiments, the difference from FIG. 12B is the package unit 14. Except for the further description, the definition of the reference symbols and labeled representations are the same as FIG. 10A and FIG. 12B, and will not be repeated herein. In some embodiments, the TIM 320 is disposed within the lid recess 340R of the lid 340, and the lid 340 is adhered to the circuit substrate 20 and the package unit 14 through the adhesive 330, the dam 350, and the TIM 320.

In some embodiments, the TIM 320 fills the lid recess 340R of the lid 340, covers the backside surfaces 102b, 104b and the sidewalls 102s, 104s of the semiconductor dies 102, 104, and covers the sidewalls 105S and the backside surface 105T of the encapsulant 105. In some embodiments, the TIM 320 disposed on the backside surfaces 102b, 104b and sidewalls 102s, 104s of the semiconductor dies 102, 104, and the backside surface 105T and the sidewalls 105S of the encapsulant 105 are beneficial for heat transfer.

Referring to FIG. 14, in some embodiments, the difference from FIG. 12B is the package unit 16. Except for the further description, the definition of the reference symbols and labeled representations are the same as FIG. 11A and FIG. 12B, and will not be repeated herein. In some embodiments, the TIM 320 is disposed within the lid recess 340R of the lid 340, and the lid 340 is adhered to the circuit substrate 20 and the package unit 16 through the adhesive 330, the dam 350, and the TIM 320.

In some embodiments, the TIM 320 fills the lid recess 340R of the lid 340, and covers the backside surfaces 102b, 104b and the sidewalls 102s, 104s of the semiconductor dies 102, 104. In some embodiments, the TIM 320 covers the backside surfaces 102b, 104b and the whole sidewalls 102s, 104s of the semiconductor dies 102, 104. In some embodiments, the TIM 320 covers the backside surfaces 102b, 104b and the whole sidewalls 102s, 104s of the semiconductor dies 102, 104, and the underfill 103. In some embodiments, the TIM 320 covers the underfill 103. In some embodiments, the TIM 320 disposed on the backside surfaces 102b, 104b and sidewalls 102s, 104s of the semiconductor dies 102, 104 are beneficial for heat transfer.

In accordance with some embodiments of the disclosure, a package structure is provided. The package structure includes a circuit substrate, a package unit disposed on and electrically connected to the circuit substrate, a molding layer disposed on the circuit substrate, a thermal interface material (TIM) disposed on the package unit; a lid disposed on the TIM and adhered to the package unit through the TIM. The molding layer surrounds the package unit and covers sidewalls of the package unit.

In accordance with some embodiments of the disclosure, a package structure is provided. The package unit includes a circuit substrate, a package unit disposed on and electrically connected to the circuit substrate, a molding layer disposed on the circuit substrate and surrounding the package unit, a thermal interface material (TIM) disposed on the package unit and in contact with a backside of the package unit, an adhesive disposed over the circuit substrate and spaced apart from the package unit, and a lid disposed on the TIM and the adhesive. The lid is adhered to the circuit substrate through the adhesive and adhered to the package unit through the TIM. The package unit includes a redistribution layer disposed on the circuit substrate, semiconductor dies disposed on the redistribution layer and electrically connected to the circuit substrate, and an encapsulant disposed on the redistribution layer and laterally wrapping the semiconductor dies. Backside surfaces of the semiconductor dies are revealed from the encapsulant.

In accordance with some embodiments of the disclosure, a method of forming a package structure is provided. A package unit is bonded to a circuit substrate. A molding layer is formed on the circuit substrate. The molding layer surrounds the package unit and covers sidewalls of the package unit. A thermal interface material (TIM) is applied on the package unit. A lid is mounted on the TIM. The lid is adhered to the package unit through the TIM

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a circuit substrate;
a package unit disposed on and electrically connected to the circuit substrate;
a molding layer disposed on the circuit substrate, surrounding the package unit and covering sidewalls of the package unit;
a thermal interface material (TIM) disposed on the package unit; and
a lid disposed on the TIM and adhered to the package unit through the TIM.

2. The package structure according to claim 1, wherein the molding layer laterally encapsulates the lid.

3. The package structure according to claim 1, further comprising:
an adhesive disposed between the molding layer and the lid,
wherein the lid is adhered to the molding layer through the adhesive.

4. The package structure according to claim 1, wherein the lid comprises:
a main portion disposed on the TIM; and
a protrusion laterally protruding from sidewalls of the main portion, and enclosing the main portion from a top view,
wherein the molding layer laterally encapsulates the main portion and the protrusion of the lid.

5. The package structure according to claim 1, wherein
the molding layer includes a recess extending from a first surface of the molding layer away from the circuit substrate into the molding layer and a bottom surface of the recess is levelled with a backside of the package unit,
the TIM is disposed on the backside of the package unit and on the bottom surface of the recess of the molding layer, and
the lid is in contact with the molding layer and the TIM.

6. The package structure according to claim 1, wherein the lid comprises:
a horizontal portion extending on the TIM and the package unit; and
a vertical portion joined with the horizontal portion and surrounding the horizontal portion,
wherein the lid encloses the molding layer and the TIM.

7. The package structure according to claim 6, further comprising:
an adhesive disposed on the circuit substrate,
wherein the lid is adhered to the circuit substrate through the adhesive and adhered to the package unit through the TIM.

8. The package structure according to claim 1, wherein
the TIM is disposed on the package unit and the molding layer, and encloses the sidewalls of the package unit.

9. A package structure, comprising:
a circuit substrate;
a package unit disposed on and electrically connected to the circuit substrate, wherein the package unit comprises:
a redistribution layer disposed on the circuit substrate,
semiconductor dies disposed on the redistribution layer and electrically connected to the circuit substrate, and
an encapsulant disposed on the redistribution layer and laterally wrapping the semiconductor dies, wherein backside surfaces of the semiconductor dies are revealed from the encapsulant;
a molding layer disposed on the circuit substrate and surrounding the package unit;
a thermal interface material (TIM) disposed on the package unit and in contact with a backside of the package unit;
an adhesive disposed over the circuit substrate, and spaced apart from the package unit; and
a lid disposed on the TIM and the adhesive, and adhered to the circuit substrate through the adhesive and adhered to the package unit through the TIM.

10. The package structure according to claim 9, wherein the lid comprises:
a horizontal portion extending on the TIM and the package unit; and
a vertical portion joined with the horizontal portion and surrounding the horizontal portion,
wherein the adhesive is disposed on the molding layer and encloses the TIM, the lid is disposed on the adhesive and encloses the TIM, and the TIM covers sidewalls of the semiconductor dies.

11. The package structure according to claim 9, wherein the TIM covers and is in contact with the backside surfaces and sidewalls of the semiconductor dies.

12. The package structure according to claim 9, wherein the TIM covers and is in contact with the backside surfaces and sidewalls of the semiconductor dies, and a backside surface and sidewalls of the encapsulant.

13. The package structure according to claim 12, wherein the backside surface of the encapsulant is lower than the backside surfaces of the semiconductor die.

14. The package structure according to claim 9, wherein the TIM is disposed on the molding layer and sandwiched between the lid and the molding layer.

15. The package structure according to claim 9, wherein the molding layer is a dam, and the dam encloses the package unit and the TIM and is spaced apart from the package unit.

16. The package structure according to claim 15, wherein the dam is disposed between the adhesive and the package unit and in contact with the lid and the circuit substrate, and the adhesive encloses the dam.

17. The package structure according to claim 15, wherein the lid comprises:
a horizontal portion including a recess, wherein the recess of the horizontal portion extending on the TIM and the package unit, and adhered to the package unit through the TIM; and
a vertical portion joined with the horizontal portion and surrounding the horizontal portion, and adhered to the circuit substrate through the adhesive,
wherein the horizontal portion of the lid is adhered to the circuit substrate through the dam, and the dam is in contact with the horizontal portion of the lid.

18. A method of forming a package structure, comprising:
bonding a package unit to a circuit substrate;
forming a molding layer on the circuit substrate, wherein the molding layer surrounds the package unit and covers sidewalls of the package unit;
applying a thermal interface material (TIM) on the package unit; and
mounting a lid on the TIM, wherein the lid is adhered to the package unit through the TIM.

19. The method according to claim 18, further comprising:
applying an adhesive on the molding layer,
wherein the adhesive is disposed between the molding layer and the lid, and the lid is adhered to the molding layer through the adhesive.

20. The method according to claim 18, wherein the lid comprises:
a horizontal portion extending on the TIM and the package unit; and
a vertical portion joined with the horizontal portion and surrounding the horizontal portion,
wherein the lid encloses the molding layer and the TIM.
